(19) United States
(12) Patent Application Publication
(10) Pub. No.: US 2026/0204524 A1
(43) Pub. Date: Jul. 16, 2026

(54) METHOD AND APPARATUS TO BIAS AN ELECTROSTATIC CHUCK

(71) Applicant: Lam Research Corporation, Fremont, CA (US)

(72) Inventor: Ashish SAURABH, Portland, OR (US)

(73) Assignee: Lam Research Corporation, Fremont, CA (US)

(21) Appl. No.: 19/135,424

(22) PCT Filed: Dec. 6, 2023
(86) PCT No.: PCT/US2023/082774

§ 371 Date: Jun. 4, 2025

Related U.S. Application Data
(60) Provisional application No. 63/387,904, filed on Dec. 16, 2022.

(51) Int. Cl. H01J 37/32

(52) U.S. Cl. CPC H01J 37/32715; H01J 37/32422; H01J 37/32568

(57) ABSTRACT

Described is one or more circuitries and method to control generation of one or more ion vacancies in an electrostatic chuck based, at least in part, on a bias applied to the electrostatic chuck. In at least one implementation, the bias applied to the electrostatic chuck comprises a conditioning voltage followed by a program voltage. In at least one implementation, the conditioning voltage has a first ramp rate which is slower than a second ramp rate of the program voltage. In at least one implementation, an end of the conditioning voltage and a beginning of the program voltage is separated in time.

### CLAIM OF PRIORITY

This application claims priority to U.S. Provisional Patent Application No. 63/387,904, filed on Dec. 16, 2022, titled “A METHOD AND APPARATUS TO BIAS AN ELECTROSTATIC CHUCK,” and which is incorporated by reference in entirety.

### BACKGROUND

Etch and deposition processes are indispensable components of modern-day semiconductor processing. While a variety of plasma processing techniques may be utilized, inductively coupled plasmas provide advantageous features such as ways to control ion energy and ion angular spread. Controlling ion energy and ion angular spread can provide a plethora of advantages for etch and deposition processes based on inductively coupled plasmas. Plasma behavior can be impacted by changing electrical parameters such as bias voltage and current on an electrostatic chuck. Methods to program biasing of an electrostatic chuck are being constantly developed to solve a variety of problems observed in semiconductor equipment operation.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1A illustrates a schematic of an apparatus including an electrostatic chuck coupled with a non-sinusoidal continuous wave voltage source, in accordance with at least one implementation.

FIG. 1B illustrates a relationship between the temperature of ions, electric field, and an angular spread in a sheath region of a plasma, in accordance with at least one implementation.

FIG. 2 is an isometric illustration of an electrostatic chuck, in accordance with at least one implementation.

FIG. 3 illustrates a plan view illustration of electrodes within the electrostatic chuck in FIG. 2, in accordance with at least one implementation.

FIG. 4A illustrates a cross-sectional illustration of an electrostatic chuck through a line A-A′ of the structure in FIG. 3, in accordance with at least one implementation.

FIG. 4B illustrates a plan view of an electrostatic chuck, in accordance with at least one implementation.

FIG. 4C illustrates a cross-sectional view of the electrostatic chuck shown in FIG. 4B, in accordance with at least one implementation.

FIG. 5 illustrates an enhanced cross-sectional illustration of a portion of the electrostatic chuck between an outer electrode and an inner electrode, in accordance with at least one implementation.

FIG. 6 illustrates a schematic representation of the inner and outer electrodes, superimposed with directions of motion of various mobile charged species and vacancies, in accordance with at least one implementation.

FIG. 7A illustrates a plot of a voltage pulse applied to one of the electrodes in the electrostatic chuck, in accordance with at least one implementation.

FIG. 7B illustrates a plot of current versus time of current flowing thorough an electrostatic chuck in response to an applied voltage pulse, in accordance with at least one implementation.

FIG. 8 illustrates a plot of current versus time of current flowing through an electrostatic chuck in response to an applied voltage pulse, in at least one implementation.

FIG. 9 illustrates a flow diagram of a method of applying a voltage pulse to an electrostatic chuck, in accordance with at least one implementation.

FIG. 10A illustrates a plot of a conditioning voltage pulse applied between electrodes in an electrostatic chuck, in accordance with at least one implementation.

FIG. 10B illustrates a plot of a current response to conditioning voltage applied between electrodes in an electrostatic chuck, in accordance with at least one implementation.

FIG. 11 is a cross-sectional illustration of the electrostatic chuck, illustrating a formation of a residual transverse electric formed after application of the conditioning voltage pulse in FIG. 10A, in accordance with at least one implementation.

FIG. 12A illustrates a plot of a conditioning voltage signal and a program voltage signal applied between electrodes in an electrostatic chuck, in at least one implementation.

FIG. 12B illustrates a plot of a current response to conditioning voltage applied between electrodes in an electrostatic chuck, in accordance with at least one implementation.

FIG. 13 is a cross-sectional illustration of the electrostatic chuck with a wafer placed on the surface, illustrating a formation of a residual transverse electric formed after application of the conditioning voltage pulse in FIG. 12A, in accordance with at least one implementation.

FIG. 14 is a cross-sectional illustration of the electrostatic chuck following the process to adsorb oxygen on at least a top surface of the electrostatic chuck, in accordance with at least one implementation.

FIG. 15 illustrates a processor system with machine-readable storage medium having instructions that when executed cause the processor to control spread in ion energy, in accordance with at least one implementation.

### DETAILED DESCRIPTION

In at least one implementation, a method to bias an electrostatic chuck is described. In the following description, numerous specific details are set forth, such as structural schemes to provide a thorough understanding of implementations of the present disclosure. It will be apparent to one skilled in the art that implementations of the present disclosure may be practiced without these specific details. In other instances, well-known features, such as radio frequency sources, and electrostatic chuck operations are described in lesser detail to not unnecessarily obscure implementations of the present disclosure. Furthermore, it is to be understood that the various implementations shown in the Figures are illustrative representations and are not necessarily drawn to scale.

In some instances, in the following description, well-known methods and devices are shown in block diagram form, rather than in detail, to avoid obscuring the present disclosure. Reference throughout this specification to “an implementation” or “one implementation” or “some implementations” means that a particular feature, structure, function, or characteristic described in connection with the implementation is included in at least one implementation of the disclosure. Thus, the appearances of the phrase “in an implementation” or “in one implementation” or “some implementations” in various places throughout this specification are not necessarily referring to the same implementation of the disclosure. Furthermore, the particular features, structures, functions, or characteristics may be combined in any suitable manner in one or more implementations. For example, a first implementation may be combined with a second implementation anywhere the particular features, structures, functions, or characteristics associated with the two implementations are not mutually exclusive.

The terms “coupled” and “connected,” along with their derivatives, may be used herein to describe functional or structural relationships between components. These terms are not intended as synonyms for each other. Rather, in particular implementations, “connected” may be used to indicate that two or more elements are in direct physical, optical, or electrical contact with each other. “Coupled” may be used to indicate that two or more elements are in either direct or indirect (with other intervening elements between them) physical, electrical, or in magnetic contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. Unless these terms are modified with “direct” or “directly,” one or more intervening components or materials may be present. Similar distinctions are to be made in the context of component assemblies. As used throughout this description, and in the claims, a list of items joined by the term “at least one of” or “one or more of” can mean any combination of the listed terms.

The term “adjacent” here generally refers to a position of a thing being next to (e.g., immediately next to or close to with one or more things between them) or adjoining another thing (e.g., abutting it).

Unless otherwise specified in the explicit context of their use, the terms “substantially,” “substantially equal,” “about equal,” and “approximately equal” mean that there is no more than incidental variation between two things so described. In the art, such variation is typically no more than +/−10% of the referred value.

Plasma etching and plasma assisted material deposition is indispensable for modern day semiconductor device manufacturing. Here, the term “plasma etching” may generally refer to a process of removing materials from a surface by charged particles and or reactive species generated by a plasma. In at least one implementation, plasmas can be utilized to etch masked material as well as maskless structures during fabrication of semiconductor devices. In at least one implementation, etching masked materials includes forming a photoresist mask over the material and using patterns in the mask to etch the material below, selectively to the mask. In at least one implementation, etching maskless structures may include removing some or all material formed in pockets selectively to surrounding material or forming spacers on sidewalls of gate electrodes in transistors. Here, the term “plasma assisted material deposition” may generally refer to a process of depositing materials onto a surface of blanket substrate or on surfaces of features formed on a substrate by charged particles and or reactive species generated by a plasma.

There are various types of tools that generate and sustain plasma, called plasma etch process tools. Here, the term “plasma etch process tools” may generally refer to an apparatus that utilizes a plasma to generate ions and reactive species to etch a material. Here, the term “plasma” may generally refer to a collection of ionized gases that are electrically neutral. In at least one implementation, plasma etch process tools can generate plasma by transformer action, electron cyclotron resonance, or capacitive methods. In at least one implementation, wafers that include materials to be etched are transported under vacuum conditions to an electrostatic chuck that is housed within a plasma processing chamber or plasma chamber. Here, the term “wafer” may generally refer to a substrate that is either conductive or insulative and includes one or more materials that are dielectric, insulative, metallic, or semi-conducting. Here, the term “electrostatic chuck” may generally refer to a support structure within the etch chamber, where wafers or substrates for processing are placed. In at least one implementation, the support structure utilizes electrostatic clamping between wafers and an uppermost surface of the chuck. In at least one implementation, the support structure may be an electrostatic chuck (ESC).

Inductively coupled plasma can offer advantages over plasma generated by other methods in that ion energies at the wafer surface can be independently controlled from ion temperatures in the plasma. Here, the term “inductively coupled plasma” may generally refer to a plasma that is generated and sustained by a transformer action external to the chamber. In at least one implementation, plasma potential and ion temperature are directly controlled by power delivered through the transformer action. In at least one implementation, ion temperatures can be controlled by transformer coupling that induces an electric field within an etch chamber. Here, the term “etch chamber” may generally refer to a chamber where plasmas are produced and wafers are plasma etched. In at least one implementation, induced electric field helps to ignite and sustain plasma and control global parameters such as electron and ion temperatures, densities etc.

In at least one implementation, plasma etch and deposition systems include electrostatic chucks. In at least one implementation, wafers can come into contact with a plasma sheath at the edge of a plasma boundary during processing. In at least one implementation, ions exit the sheath with a spread in ion energy and ion angular spread. In at least one implementation, ion energies are controlled by a bulk plasma potential but can also be controlled by biasing the electrostatic chuck.

In at least one implementation, an electrostatic chuck can include a bipolar chuck, where biasing the electrostatic chuck includes applying a time varying sinusoidal voltage between two electrodes. In at least one implementation, a positive voltage is applied to a first electrode and a negative voltage is applied to a second electrode, where the positive and negative voltage pulses have a same or substantially a same voltage level and a same periodicity. In at least one implementation, voltage biasing process can take place every time a substrate is placed on the electrostatic chuck to be processed.

While placing and removing substrates (e.g., process wafers) can cause physical wear and tear on surface of the electrostatic chuck, voltage biasing to sustain plasmas, as well as voltages applied for electrostatic clamping of process wafers, can cause internal wear within a dielectric body of the electrostatic chuck. In at least one implementation, an electrostatic chuck includes at least a pair of conductive electrodes embedded within a dielectric (e.g., ceramic) body. An insulator layer comprising a dielectric material making up the bulk of the chuck body may cover the conductive electrodes. A substrate, such as a process semiconductor wafer, is to be clamped to this insulator layer. In at least one embodiment, an additional insulator layer may be present between the substrate and the ceramic material, preventing currents to flow across a semiconductor substrate (e.g., process wafer) when voltages are applied to the chuck for electrostatic clamping of the semiconductor substrate. In at least one implementation, when biasing and/or clamping voltages of 500V or higher are applied to an electrostatic chuck, strong local electric fields can cause movement of mobile charged species, such as ionic vacancies and interstitials, within the electrostatic chuck.

In at least one implementation, there are three main degradation modes for the dielectric (e.g., an ionic ceramic) material comprised by the body of an electrostatic chuck. For example, degradation may occur through a change in the population of mobile charged species, through a change in the charge mobility, or through mechanical changes such as creation of voids, which may result in delamination of embedded electrodes and cracks within the ceramic. Such mechanical changes may result in mechanical failure of the electrostatic chuck after a period of time.

In at least one implementation, the dielectric body material of an electrostatic chuck can include charged vacancies of constituent species. For example, when an electrostatic chuck body includes aluminum nitride (AlN), aluminum vacancies (a negatively-charged mobile charged species) may be present within grains of aluminum nitride. Because aluminum vacancies are mobile, they can respond to electric fields. Motion of aluminum vacancies under the influence of electric fields resulting from application of DC bias and clamping voltages to electrodes embedded within the electrostatic chuck body can give rise to ionic currents. Such currents may flow within the dielectric portion of an electrostatic chuck between two oppositely charged electrodes. Such ionic currents can be large enough to cause voltage fluctuations at the surface of the electrostatic chuck, where substrates are placed for processing. Besides aluminum vacancies, other forms of charged particles, such as oxygen ion vacancies (a positively-charged mobile charged species) can also be present within the electrostatic chuck. Motion of oxygen ion vacancies can also add to the ionic current within the dielectric body of an electrostatic chuck.

While surfaces of the electrostatic chuck may appear to be smooth and substantially homogenous, there may be microscopic voids present within the body of an electrostatic chuck. Voids can enable partial discharges to occur. Partial discharges are known to occur within voids in ceramic insulative materials as large electric fields that develop across microscopic voids, created by application of high voltages on the bulk ceramic host material, exceed the dielectric breakdown field strength of the bulk ceramic material (e.g., resulting from the dielectric constant within the void that is much smaller than that of the bulk, resulting in significantly higher electric fields within voids relative to bulk. In an electrostatic chuck, such static discharges can subsequently cause momentary disruptions at the plasma-wafer boundary. While some voids may be inherently present within the dielectric body of an electrostatic chuck prior to placement in service, other voids may be created by reduction of constituent species within body of the electrostatic chuck after placement in service. Voids can be created by high voltage ramp phases during biasing the electrostatic chuck due to electromigration of oxygen and aluminum ions within the solid phase. Such electromigration may occur within individual grains and between grains within a polycrystalline dielectric material, whereby ions cross grain boundaries. In AlN, both aluminum and oxygen ions may migrate along grain boundaries, for example.

While ionic currents can be observed in the electrostatic chuck during routine operation, when the electrostatic chuck starts to become degraded, the magnitude of ionic current can start to increase rapidly. Increase in ionic current may arise from increase in vacancies within the chuck as will be explained below.

In at least one implementation, methods to mitigate adverse effects of increase in ionic current are used. In at least one implementation, methods include voltage biasing schemes with long ramp times.

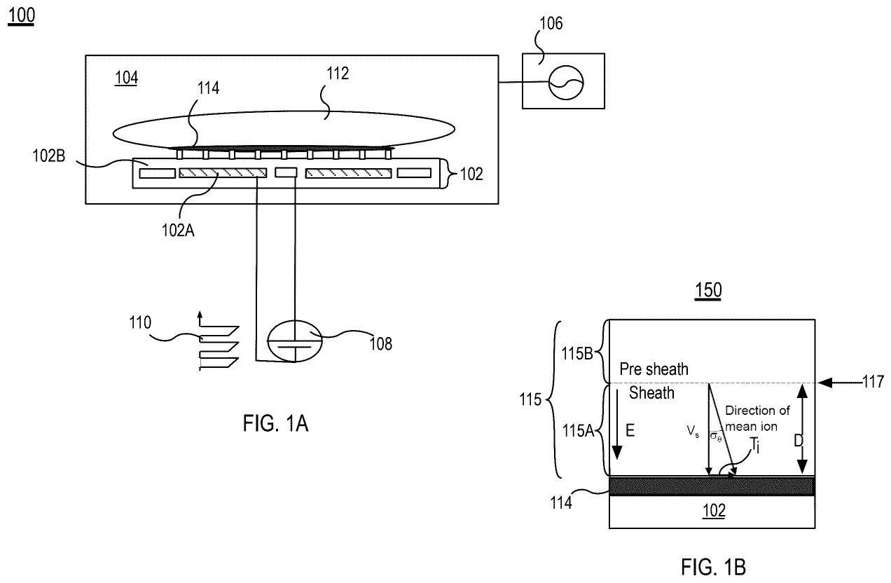

FIG. 1A illustrates a schematic of plasma processing tool 100, in accordance with at least one implementation. In at least one implementation, plasma processing tool 100 is an inductively coupled etch tool. In at least one implementation, plasma processing tool 100 includes an electrostatic chuck 102 within process chamber 104. In at least one implementation, plasma processing tool 100 includes an RF generator 106 coupled with coils above process chamber 104. In at least one implementation, plasma processing tool 100 is an inductively coupled deposition tool. In at least one implementation, plasma processing tool 100 may include voltage generator 108 coupled with electrostatic chuck 102.

In at least one implementation, electrostatic chuck 102 includes electrodes 102A coupled with voltage generator 108, and an insulator 102B encasing electrodes 102A. In at least one implementation, insulator 102B may include polycrystalline dielectric materials including alloys and ceramics such as alumina (Al₂O₃), silicon dioxide (SiO₂), silicon nitride (Si₃N₄), aluminum nitride (AlN), zirconium oxide (ZrO₂), or sapphire (Al₂O₃ matrix containing iron, vanadium and cobalt impurities). In at least one implementation, electrostatic chuck 102 includes an amorphous or polycrystalline ceramic such as AlN or ZrO₂. In at least one implementation, ceramics are ionic solids and their degradation can occur through several mechanisms, including but not limited to solid electrolyte interphase (SEI) layer change, mechanical effects in the particles (where mobile charged species may be free to move in the electrolyte as mobile charge carriers), and electrolytic oxidation or reduction. While AlN is commonly employed as the dielectric ceramic material within insulator 102B due to its durability and other mechanical characteristics, in at least one implementation, electrostatic chuck 102 may include multiple dielectric materials such as those listed above beside or other than AlN.

In at least one implementation, electrostatic chuck 102 can include grooves within insulator 102B for substrate 114 during processing. In at least one implementation, voltage generator 108 may be configured to produce a pulsed voltage waveform 110 applied to electrodes 102A within electrostatic chuck 102.

In at least one implementation, during operation, plasma 112 may be generated within process chamber 104. In at least one implementation, ions are ejected from a plasma sheath, an outmost portion of plasma 112 that may be at the vicinity of insulator 102B. In at least one implementation, plasma sheath may be a non-neutral region formed at a plasma boundary to balance electron and ion losses to maintain quasi-neutrality. In at least one implementation, ions impinge onto substrate 114 placed on electrostatic chuck 102 and perform a variety of etching (e.g., chemical, mechanical etc.) of one or materials within substrate 114. In at least one implementation, ions can assist with deposition of material on substrate 114.

In at least one implementation, the characteristics of the ions such as velocity and angular distribution within the sheath region of plasma 112 depend on plasma potential and potential at surface of substrate 114, which may be controlled by a voltage applied to electrostatic chuck 102. In at least one implementation, velocity of ions may be directly influenced by both plasma potential and potential at surface of substrate 114. In at least one implementation, an increase in both plasma potential and potential at surface of substrate 114 increases an electric field that drives ions towards electrostatic chuck 102. In at least one implementation, an electric field in a bulk portion of plasma may be substantially small (e.g., 10V/cm or less) but field in a sheath region (adjacent to substrate 114) can be about 1 kV/cm. In at least one implementation, any fluctuations in voltage at substrate due to degradation in electrostatic chuck can potentially impact both deposition and etch processes at the substrate.

In at least one implementation, one of the quantities affected by voltage bias fluctuations is angular spread in ions. In at least one implementation, relationship between temperature of ions in plasma 115, voltage applied to sheath 115A, and the angular spread is illustrated in diagram 150 in FIG. 1B. In at least one implementation, plasma 115 typically includes sheath 115A and presheath 115B adjacent to sheath 115A. In at least one implementation, voltage of an ion at boundary 117 between sheath 115A and presheath 115B, relative to voltage V_{S}, supplied to a surface of substrate 114 creates a net electric field E, in sheath 115A. In at least one implementation, sheath voltage V_{S} determines thickness D of sheath 115A. In at least one implementation, electric field E is a function of the power supply coupled to sustaining plasma 112 and raises a potential of plasma 112 to levels used to sustain plasma 112. In at least one implementation, electric field, E is directed towards electrostatic chuck 102. In at least one implementation, lateral component of ion velocity due to temperature Tᵢ of ions arises from random motion of ions in plasma 112. In at least one implementation, vector sum of ion velocity due to temperature Tᵢ and velocity due to sheath voltage V_{S} provides a maximum ion angular spread, sigma theta.

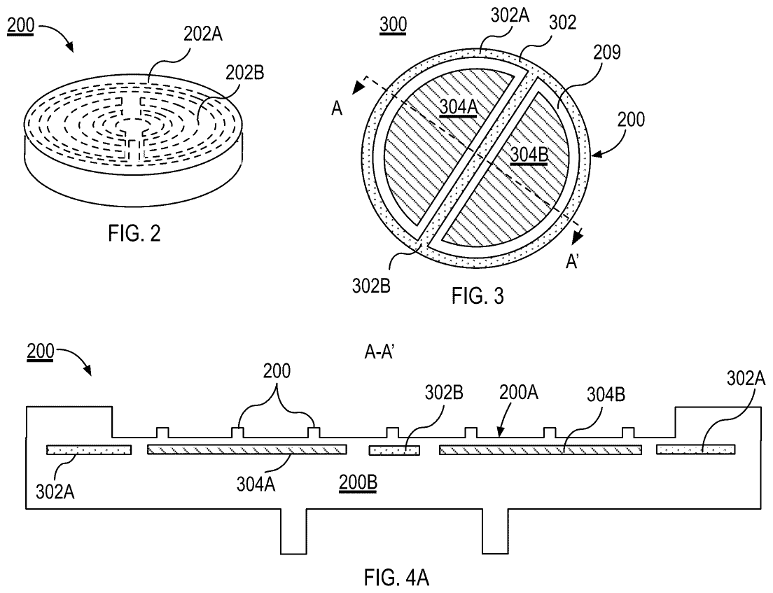

In at least one implementation, a relationship between the temperature of ions Tᵢ voltage supplied to the ions within the sheath V_{S}, and of the angular spread in ion velocity illustrated in FIG. 2, may be expressed by equation 1.1:

$${σ}_{θ} = {tan}^{- 1} ( \sqrt{{kT}_{i} / {qV}_{s}} ) , \qquad ( 1.1 )$$

where σ_{θ} is an angular spread, Tᵢ is temperature of ions in process chamber 104 (FIG. 1A), q is the charge of an electron in coulombs, k is the Boltzmann constant, and V_{S} is the sheath voltage.

In at least one implementation, angular spread, theta, of ions accelerating towards an electrostatic chuck 102, is directly influenced by a ratio between Tᵢ and sheath voltage V_{S}. In at least one implementation, sheath voltage V_{S} is set by a pulsed voltage applied to electrostatic chuck 102. In at least one implementation, changes in voltage applied to electrostatic chuck 102 can directly impact ions impinging the wafer.

In at least one implementation, electrostatic chuck 102 is voltage biased by a radio frequency (RF) voltage waveform to induce an RF voltage on the wafer. In at least one implementation, RF voltage induced on the wafer overcomes capacitive effects of insulator 102B. In at least one implementation, tuning the RF voltages overcomes a steady rise in potential at wafer due to a steady ion flux. In at least one implementation, RF biasing electrostatic chuck 102 can change sheath voltage V_{S}. In at least one implementation, due to low pressure discharges in inductively coupled plasmas, sheath 115A may be generally considered to be collision-less and relatively narrow (e.g., in the order of a few millimeters). In at least one implementation, as RF voltage approaches a kilovolt level in dielectric-lined chambers, for example, sheath 115A may become collisional. In at least one implementation, the response of ions to an RF voltage waveform influences etching characteristics on a wafer surface. In at least one implementation, the voltage level of the RF voltage waveform and its oscillation frequency can shape ion energy distributions. In at least one implementation, the magnitude of the voltage and frequency of oscillations can shape ion energy distributions as well as ion angular spread at the wafer surface. In at least one implementation, adverse effects such as current spikes (e.g., ionic current) at electrode 102A, can lead to process degradation and substrate loss.

FIG. 2 illustrates an isometric illustration of electrostatic chuck 200, in at least one implementation. In at least one implementation, electrostatic chuck 200 includes features of electrostatic chuck 102 described in association with FIG. 1A. In at least one implementation, electrostatic chuck 200 includes heater electrodes 202A and 202B to heat substrate during processing. In at least one implementation, heater electrode 202A is an outer heater electrode, and heater electrode 202B is an inner heater electrode. In at least one implementation, heater electrodes 202A and 202B can be utilized to heat electrostatic chuck 200 to temperatures above 500 degrees Celsius. In at least one implementation, a ramp rate of heater electrodes 202A and 202B can be 5 degrees/second. In at least one implementation, heater electrodes 202A and 202B can be forward programmed so that when a substrate is placed on surface 200A of electrostatic chuck 200, temperature of wafer quickly reaches equilibrium conditions. In at least one implementation, heating and cooling of electrostatic chuck 200 can lead to a failure mode such as creation of numerous voids within electrostatic chuck 200 and associated charge-driven current spikes caused by discharges occurring within the voids.

FIG. 3 illustrates a plan view illustration 300 of electrodes 302, 304A and 304B within electrostatic chuck 200 in FIG. 2, in at least one implementation. Components such as heater elements are not illustrated to provide clarity. In at least one implementation, electrostatic chuck 200 includes electrode 302 and collectively electrodes 304A and 304B for bipolar operation. In at least one implementation, electrode 302 includes electrode 302A and electrode 302B, where electrode 302A and electrode 302B are contiguous. In at least one implementation, electrodes 304A and 304B are symmetric about electrode 302B. In an implementation, electrodes 304A and 304B are biased to the same potential simultaneously, while electrode 302 is biased to a different potential. In at least one implementation, electrodes 304A and 304B are biased to an opposite polarity to electrode 302.

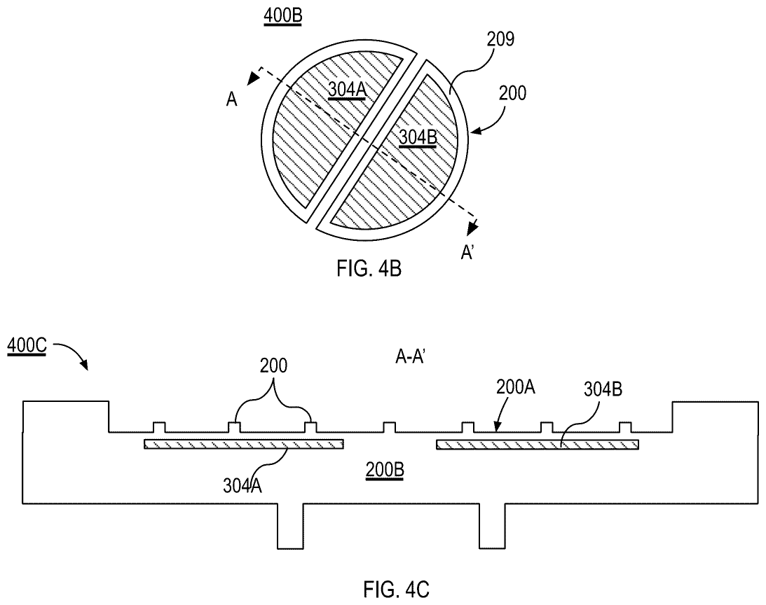

FIG. 4A illustrates a cross-sectional illustration of electrostatic chuck 200 through a section line A-A′ of the structure in FIG. 3, in accordance with at least one implementation. In at least one implementation, electrostatic chuck 200 includes one or more features of electrostatic chuck 102 (FIG. 1A) and electrostatic chuck 200 (FIG. 3). In at least one implementation, electrodes 304A, 304B, 302A, and 302B are spatially directly under surface 200A. In at least one implementation, electrodes 304A, 304B, are spatially separated from electrodes 302A and 302B by region 209 of platen body 200B, and by portions of platen body 200B of electrostatic chuck 200. In at least one implementation, while platen body 200B of electrostatic chuck 200 is an insulator, when electrodes 304A, 304B, 302A, and 302B are voltage biased, charges may move within platen body 200B of electrostatic chuck 200. In at least one implementation, such charges include aluminum and oxygen vacancies as well as free electrons and ions. In at least one implementation, examples of motion of charges within platen body 200B are discussed below.

FIG. 4B illustrates a plan view of electrostatic chuck 200 (herein, electrostatic chuck 400B), in accordance with at least one implementation. In at least one implementation, electrostatic chuck 400B comparatively includes one or more features of electrostatic chuck 200 shown in FIGS. 2, 3, and 4A with the exception that electrodes 302A and 302B, are omitted. In at least one implementation, electrostatic chuck 400B still comprises electrodes 304A and 304B, disposed symmetrically below surface 200A, which perform the electrostatic clamping function. In at least one implementation, electrodes 304A and 304B have semicircular shapes that extend bilaterally from a center diameter to toward the periphery of electrostatic chuck 400B.

FIG. 4C illustrates a cross-sectional view of electrostatic chuck 200 (herein electrostatic chuck 400C), in accordance with at least one implementation. The cross-sectional view shown in FIG. 4C is taken through section line B-B′ of FIG. 4B. In FIG. 4C, electrodes 304A and 304B are disposed symmetrically within platen body 200B below surface 200A.

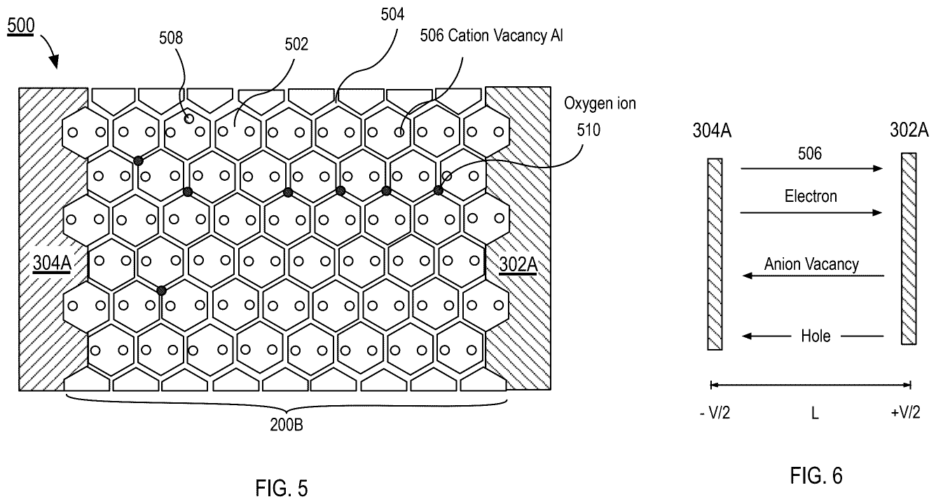

FIG. 5 illustrates an enhanced cross-sectional illustration of a portion 500 of electrostatic chuck 200 between electrode 304A and electrode 302A, in at least one implementation. In at least one implementation, material composition of platen body 200B can be represented by a plurality of grains 502. In at least one implementation, individual grains in the plurality of grains 502 are identical.

In at least one implementation, grain boundaries 504 are located between adjacent grains 502. While grain boundaries are illustrated by gaps, such gaps are shown for clarity. In actual material of platen body 200B, adjacent grains 502 are in contact with each other, in accordance with at least one implementation. In at least one implementation, platen body 200B comprises aluminum nitride. In at least one implementation, platen body 200B can comprise a population of mobile charge species that may include cation vacancies 506 (e.g., aluminum ion vacancies) and anion vacancies 508 (e.g., oxygen ion vacancies). While mobile charge species may include any type of monocrystalline and polycrystalline defect, cation and anion vacancies are mentioned in exemplary fashion herein. Cation and anion vacancies are principal defects associated with structural damage in AlN and other refractory ceramic materials employed in electrostatic chucks due to migration induced by strong field in electrostatic chucks. In at least one implementation, cation vacancies 506 carry a negative charge. In at least one implementation, negative charge or valency of cation vacancies 506 may be equivalent to a valency of three negative charges. In at least one implementation, anion vacancies carry a positive charge. In at least one implementation, positive charge or valency of anion vacancies may be equivalent to a valency of two positive charges. While both types of vacancies may be present with grains 502, anion (e.g., oxygen) vacancies 508 may dominate, in at least one implementation.

FIG. 6 illustrates a schematic representation of electrodes 304A and 302, superimposed with directions of motion (denoted by arrows) of various mobile charged species, including ionic carriers and such as interstitial oxygen ions, cation, and anion vacancies, as well as electronic carriers, such as electrons and holes, during a snapshot of time, in accordance with at least one implementation. In at least one implementation, arrows point in the direction of flow of different mobile charged species toward electrode 304A or 302A, where electrode 304A is negatively charged and electrode 302A is positively charged. In at least one implementation, cation vacancy 506 and electrons are directed towards electrode 302A, and anion vacancy 508 and holes are directed towards electrode 304A. In at least one implementation, flows and electrode biasing are reversed from that illustrated.

Referring again to FIG. 5, in at least one implementation, when voltage is applied to electrodes 302A and 304A, cation vacancies 506 and anion vacancies 508 may migrate within grains 502 in response to an electric field applied across platen body 200B. In at least one implementation, if electrode 304A is negative and electrode 302A is positive, negatively charged cation vacancies 506 may migrate within grains 502 toward positive electrode 302A. In at least one implementation, positively charged anion vacancies 508 may migrate within grains 502 toward negative electrode 304A. In at least one implementation, cation vacancies 506 (e.g., oxygen vacancies) and anion vacancies 508 (e.g., aluminum vacancies) become pinned at grain boundaries 504. In at least one implementation, cation vacancies 506 and anion vacancies 508 may not travel across grain boundaries 504. In at least one implementation, cation vacancy 506 and anion vacancy 508 may not cross material boundaries within platen body 200B and electrodes 304A and 302A. In at least one implementation, movement of charged cation vacancies 506 and anion vacancies 508 in an applied electric field generates an ionic current.

In at least one implementation, upon application of an electric field, ionic motion may be initiated within platen body 200B. In at least one implementation, ionic current flowing between electrodes 304A and 302A may be transient, where its transient nature may be due to pinning of cation vacancies 506 and anion vacancies 508 at grain boundaries 504, causing the ionic current to decay over time. In at least one implementation, ionic current may be characterized as a spike phase followed by an exponential decay phase after application of a voltage pulse or step as will be described below. In at least one implementation, the exponential decay phase may have a time constant that is related to the mobility of cation vacancies 506 and to anion vacancies 508.

In at least one implementation, interstitial oxygen ions 510 may be present, as shown in FIG. 5. In at least one implementation, interstitial oxygen ions 510 may be located along grain boundaries 504. In at least one implementation, interstitial oxygen ions 510 may also move in response to an imposed electric field. In at least one implementation, oxygen ions 510 may migrate along grain boundaries 504 toward the positive electrode, and generally may not be restricted to remain within a particular grain 502. In at least one implementation, during transit, some oxygen ions 510 may become pinned at defects encountered along grain boundaries 504. Many oxygen ions 510 may migrate toward a boundary between platen body 200B and positive electrode (e.g., electrode 304A or 302A). In at least one implementation, some migrating oxygen ions 510 may encounter some pinned oxygen ions 510, and begin to accumulate, forming clusters. In at least one implementation, accumulation of oxygen ions 510 may create voids and/or adventitious heterogeneous crystalline phases comprising aluminum oxide and/or aluminum oxynitride within platen body 200B. For example, aluminum oxide or aluminum oxynitride phases may be formed. In at least one implementation, anion vacancies 508 can occur during intra-grain transit. In at least one implementation, accumulation of anion vacancies 508 can result in similar void formation and formation of adventitious material phases.

In addition to cation vacancies 506 and anion vacancies 508, in at least one implementation, a population of charge balancing free electrons (not shown), and to a smaller extent, holes (not shown), may be present within platen body 200B because of the charged vacancy and interstitial crystalline defects. In at least one implementation, these charges also move under the influence of an electric field. In at least one implementation, free electrons and holes have significantly larger drift mobilities within platen body 200B than ion vacancies (cation vacancies 506 and anion vacancies 508 and interstitials). In at least one implementation, free electrons and holes can cross grain boundaries 504, permitting electronic current flow. In at least one implementation, in this manner, platen body 200B may behave as an n-doped wide bandgap semiconductor.

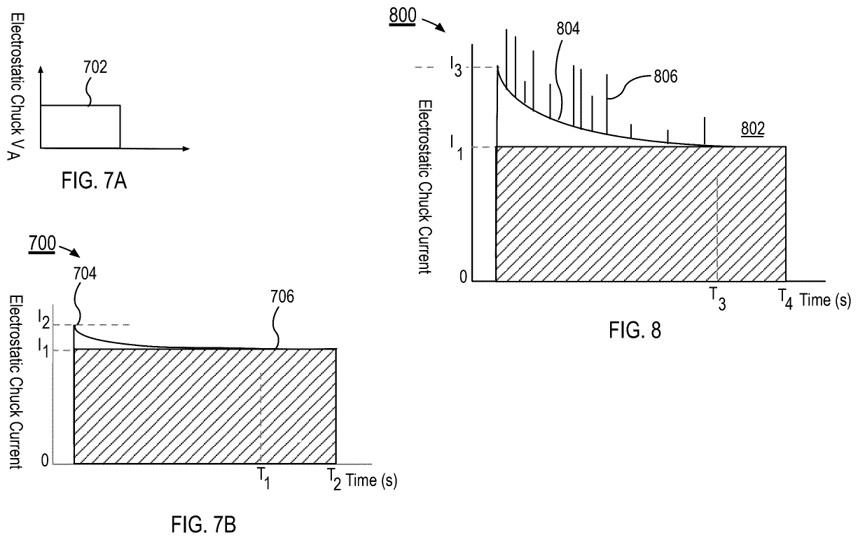

In at least one implementation, upon application of an electric field across platen body 200B, a measured current may comprise an ionic current component superimposed upon an electronic current component. A current characteristic of platen body 200B is shown in FIG. 7A, in accordance with at least one implementation. In at least one implementation, the current characteristic may comprise an initial spike, followed by exponential decay to a steady state current. In at least one implementation, steady state current may be representative of electronic current component as discussed above.

FIG. 7A illustrates plot 700 of a voltage pulse 702 applied to one of electrodes in electrostatic chuck 200, in at least one implementation. In at least one implementation, voltage pulse 702 may represent a high voltage square wave applied to electrodes (for example electrodes 302A and 304A within electrostatic chuck 200). In at least one implementation, voltage pulse 702 may represent a long duration high voltage pulse, having an on-time of several hours. In at least one implementation, voltage pulse 702 may have a rise time of less than 3 seconds to reach steady state values ranging between 300 volts and 6000 volts. In at least one implementation, voltage pulse 702 may represent a voltage pulse that may produce a current response such as illustrated by electrostatic chuck current in plot 700 in FIG. 7B.

FIG. 7B illustrates plot 700 of current versus time of current flowing through a body of an electrostatic chuck in response to an applied voltage pulse, in at least one implementation. In at least one implementation, current in plot 700 may be measured across platen body 200B between electrodes 302A and 304A (e.g., FIGS. 4A-C).

In at least one implementation, biasing voltages may range from 300V to 6000V. In at least one implementation, in an initial phase of plot 700, a transient current spike 704 may be observed in response to rising edge of biasing voltage. In at least one implementation, transient current spike 704 reaches an electrostatic chuck current level I₂ and may decay exponentially thereafter, leveling off to I₁, which may be a value of steady-state (electronic) current 706.

In at least one implementation, an exponential decay time constant may include kinetic rates of ionic mobility within platen body 200B of electrostatic chuck. In at least one implementation, decay time constant may be several tens of minutes. In at least one implementation, steady state current 706 (e.g., I₁) may be reached after several time constants or after time T₁. In at least one implementation, transient current spike 704 may decay to steady state current 706 after a time T₁ that is approximately 100 minutes or more.

In at least one implementation, steady state current 706 (I₁) may be a fraction of peak current I₂ of transient current spike 704. In at least one implementation, level of current I₁ may be 80% of level of current I₂. In at least one implementation, transient current spike 704 may increase relative to steady state current 706 over time as electrostatic chuck 200 is implemented. In at least one implementation, stress related to electromigration of cation and anion vacancies (e.g., cation vacancies 506 and anion vacancies 508) within the dielectric material may cause aging of electrostatic chuck 200.

FIG. 8 illustrates plot 800 of current versus time of current flowing through an electrostatic chuck in response to an applied voltage pulse, in at least one implementation. In at least one implementation, an electrostatic chuck utilized in generating plot 800 is representative of an electrostatic chuck that is at failure. In at least one implementation, failure may be characterized by a transient current 804 of plot 800 where the transient current rises initially to a peak current I₃ in response to the rising edge of a biasing voltage applied to electrodes, such as electrodes 302A and 304A (e.g., FIGS. 4A-C). As noted above, the biasing voltage may be applied as a square wave pulse, such as the square wave voltage waveform represented by voltage pulse 702 (FIG. 7A). In at least one implementation, transient current 804 decays exponentially to a value of steady state current I₁, represented by steady state region 802.

In at least one implementation, the behavior depicted in plot 800 is representative of material where a combination of high levels of ion vacancy motion and prevalence of voids within give rise to an initially high transient ionic current, indicated by the initial component of the current-voltage characteristic, as well as numerous breakdown spikes, such as current spike 806. Transient ionic currents may reach an initial current level I₃ that is 10-15 times larger than base steady state current I₁. The transient current decays exponentially, indicative of a first order ionic transport process, to a steady state electronic current that is due to drift of electronic carriers dominating ionic current.

In at least one implementation, when electrostatic chuck approaches failure mode, transient current 804 comprises current spikes such as current spike 806. In at least one implementation, current spikes may occur randomly, and have a duration from less than a second to several seconds. Current spikes may be caused by electric arc discharges or partial discharges within microscopic voids formed by vacancies, for example, or within microscopic voids or other defects such as dislocations within bulk dielectric material of an electrostatic chuck.

In at least one implementation, current spikes may arise due to partial discharges within body of electrostatic chuck 200. In at least one implementation, the term “partial discharges” may generally refer to microscopic sparks or electric arc discharges that can be associated with dielectric breakdown that occurs within a cavity, such as a small void, formed within the body of electrostatic chuck. In at least one implementation, breakdown may occur when a localized electric field within a void or space is stronger than an averaged electric field applied over a larger region containing void, such that the localized electric field causes a breakdown. In at least one implementation, the effect of such breakdown may cause a current spike.

Void population within a ceramic electrostatic chuck body (e.g., platen body 200B) may increase with repeated application of voltage biasing of electrodes over time. In at least one implementation, plot 800 may be obtained after an electrostatic chuck has been in service for approximately one month. In at least one implementation, an electrostatic chuck may be subject to thousands of clamping operations per day. Void formation within dielectric material of electrostatic chuck may lead to chuck failure. An eventual replacement of the aged chuck with a new chuck is generally very costly.

In some implementations, current spikes can adversely impact a substrate voltage during wafer processing. For example, current spikes at the surface of the substrate can cause electrical damage to one or more features within the substrate or cause fluctuations in sheath potential (discussed in FIG. 1B).

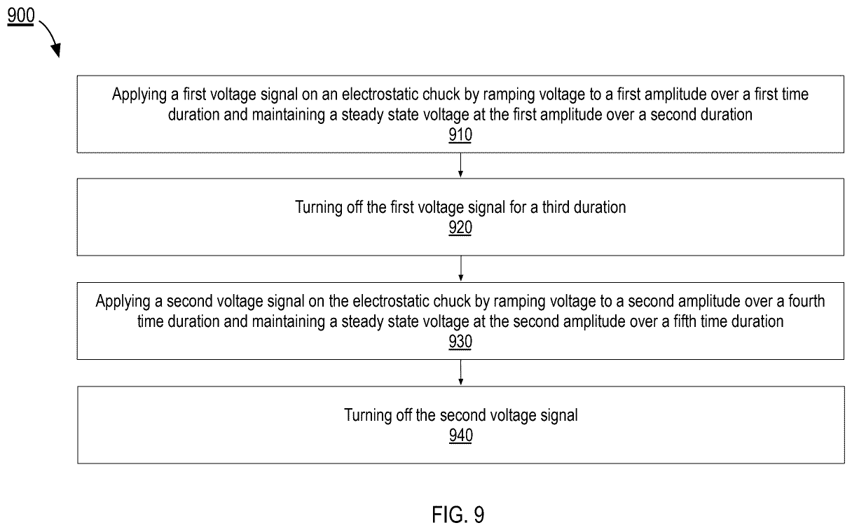

FIG. 9 illustrates a flow diagram of a method 900 of applying a voltage pulse to an electrostatic chuck, in at least one implementation. Method 900 can be performed by software, hardware, or a combination of them. In at least one implementation, to ameliorate mechanical stress, ionic current increase within a body of electrostatic chuck 200, a voltage bias scheme may be implemented. In at least one implementation, method 900 begins at operation 910 by generating a first voltage signal, where the first voltage signal comprises a ramp to a first voltage level over a first duration and maintaining a first steady-state voltage with the first voltage level for a second duration. In at least one implementation, the first voltage signal effectuates a first current at a surface (e.g., surface 200C) of electrostatic chuck 200. In at least one implementation, the first steady-state voltage level is a conditioning voltage. In at least one implementation, at operation 920, the first voltage signal is stepped to a reference voltage level (e.g., zero volts) for a third duration. In at least one implementation, at operation 930, a second voltage signal is generated. In at least one implementation, the second voltage signal comprises a ramp to a second steady-state voltage level over a fourth duration and maintaining a second steady state voltage with the second voltage level for a fifth duration. In at least one implementation, the second steady-state voltage level is a program voltage. In at least one implementation, at operation 940 second voltage signal is stepped to the reference voltage level (e.g., zero volts).

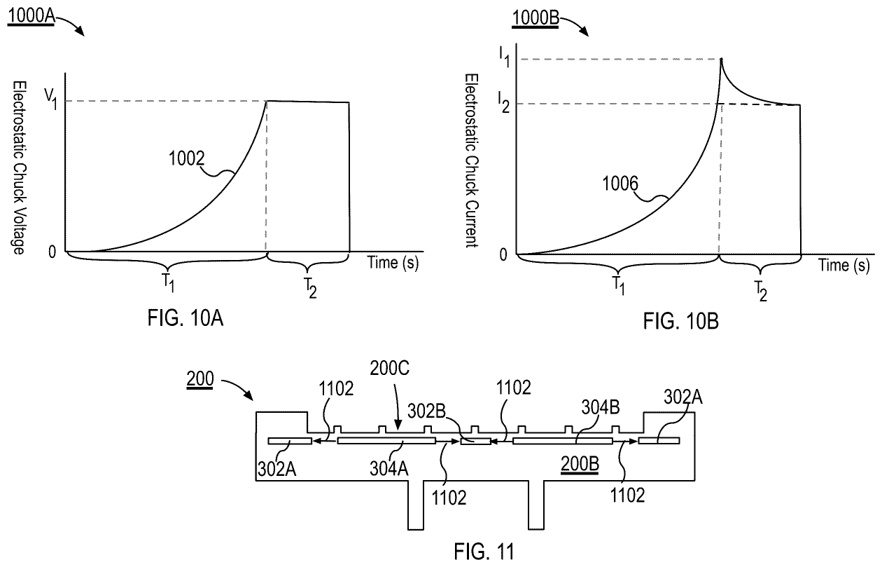

FIG. 10A illustrates time-domain plot 1000A of a conditioning voltage signal applied to a first electrode in a pair of electrodes in an electrostatic chuck, in accordance with at least one implementation. In at least one implementation, a voltage signal of an opposite polarity may be applied to a second electrode in the pair of electrodes. In at least one implementation, an electrode pair may comprise electrodes 302A and 304A, electrodes 304A and 304B, or electrodes 302A, 302B, and 304A and/or 304B.

In at least one implementation, a voltage bias scheme may be implemented to ameliorate mechanical stress and reduce ionic current transients within platen body 200B of electrostatic chuck 200 that can occur when clamping voltages are applied (e.g., see FIG. 11). In at least one implementation, plot 1000A illustrates voltage signal 1002 in the time domain that comprises a linear or a non-linear ramp over a duration Tᵢ as depicted, to a voltage steady level V₁. In at least one implementation, voltage V₁ is between 300-6000 volts, and may be imposed for a duration T₂. In at least one implementation, V₁ and associated electric fields can be of a selected or optimized magnitude and the profile of charging and discharging may be tuned to accommodate charge mobility. In at least one implementation, ramp and/or plateau voltage of voltage signal 1002 can be adjusted autonomously by software, hardware, or a combination of them. Adjustment of the ramp duration and/or voltage level of voltage signal 1002 may be performed to optimize a particular conditioning regime. In at least one implementation, the ramp phase of voltage signal 1002 can be slowed by increasing duration T₁ to implement a soft charging conditioning procedure.

In at least one implementation, voltage is ramped over duration T₁ which can be between 5 seconds and 180 seconds. In at least one implementation, a voltage ramp over duration T₁ offers benefits in a form of reduced stress to the ceramic material within platen body 200B of electrostatic chuck 200. In at least one implementation, a slowly increasing voltage can reduce the rate at which ion vacancy migration can take place within platen body 200B between electrodes 302A and 304A (e.g., see depiction of flow of charge carriers between electrodes in FIG. 6). In at least one implementation, the voltage is ramped at a rate of 50 V/s (volts per second) to 165 V/s. An advantage of reducing ionic current is a reduction in the current output capacity of the voltage source which can be utilized to program electrostatic chuck 200. In at least one implementation, voltage signal 1002 is held at a steady state voltage at steady-state voltage level V₁ for a duration T₂.

In at least one implementation, duration T₂ can vary with method of control. In at least one implementation, duration T₂ can range between 5s and 180s. In at least one implementation, the ramp and steady-state voltage level V₁ portions of voltage signal 1002 are pre-charge voltages employed in a pre-charge conditioning sequence for reversing accumulation of mobile charged species, particularly in the form of voids formed from accumulated oxygen ion vacancies. In at least one implementation, voltage signal 1002 is applied in a polarity that is opposite of the polarity of clamping voltages applied during wafer processing. Voids may form over time within the dielectric material (e.g., AlN) of the electrostatic chuck due to electromigration of oxygen ion vacancies over a particular path between clamping electrodes. Electromigration of oxygen ion vacancies (e.g., a positively-charged mobile charged species) to form voids within the dielectric platen body can be induced by repeated application of clamping voltages, which may range between 500 volts and 1000 volts. Voids may coalesce and grow over repeated processing runs requiring electrostatic clamping of the process wafer, ultimately leading to mechanical failure of the electrostatic chuck. Furthermore, void accumulation may develop filaments extending between clamping electrodes. Aluminum ion vacancies (a negatively-charged mobile charged species) and interstitial cations (e.g., aluminum ions, positively-charged mobile charged species) may migrate within the ceramic material in opposite directions under the influence of an applied electric field resulting from the clamping voltage on the clamping electrodes. As a result, long-lived residual electric fields due to the separated ionic charges may develop within the ceramic material between the clamping electrodes, causing RF and DC biases applied to the electrostatic chuck during plasma deposition to be positionally skewed and/or have altered magnitudes. The final result may be poor quality growth of films on the process wafers.

Application of voltage signal 1002 may be applied prior to each wafer processing run or prior to a sequence of wafer processing runs to mitigate void formation and growth. In at least one implementation, the polarity of voltage signal 1002 may be applied substantially in opposition to the polarity of the clamping voltage.

In at least one implementation, voltage signal 1002 effectuates a current at a surface (e.g., surface 200C) of electrostatic chuck 200 that is illustrated by plot 1000B shown in FIG. 10B. In at least one implementation, current signal 1006 comprises a ramp and a current spike having a maximum I₁ decaying to a magnitude I₂. In at least one implementation, the maximum current level of current signal 1006 reaches its peak at the end of the first duration T₁. In at least one implementation, current signal 1006 decays to magnitude I₂ to reach a steady state current due to electronic carrier drift over duration T₂. In at least one implementation, duration T₂ may range between 5s and 180s, and preferably between 10s and 30s

In at least one implementation, I₂ may be between 80% and 90% of I₁. In at least one implementation, magnitude of I₂ in plot 1000B is indicative of current response on electrostatic chuck 200 depicted in FIG. 7B.

FIG. 11 is a cross-sectional illustration of electrostatic chuck 200 at the end of duration T₂, in at least one implementation. In at least one implementation, voltage signal 1002 is turned off (e.g., not applied) after duration T₂. FIG. 11 illustrates the existence of residual electric fields 1102 formed in the ceramic material (e.g., AlN) between electrodes within platen body 200B during application of the conditioning voltage pulse in FIG. 10A, in at least one implementation. In at least one implementation, residual electric fields 1102 are parallel to surface 200C. In at least one implementation, residual electric fields 1102 are formed in platen body 200B upon application of bias voltages on electrodes 302A, 302B, 304A, and 304B. Residual electric fields 1102 may extend between oppositely charged electrodes. Exemplary polarities of residual electric fields 1102 are indicated by the directions of the various vector arrows pointing left and right in FIG. 11. For example, one of electric fields 1102 may extend between electrodes 302A and 304A, where the direction of the vector arrow indicates that the electric polarity of electrode 302A was negative with respect to electrode 304A during application of the bias voltage pulse. Similarly, electrodes 304A and 304B were held positive with respect to electrode 302B during application of the voltage bias pulse, as indicated by the directions of the vector arrows pointing to electrode 302B in the implementation shown in FIG. 11.

In at least one implementation, residual electric fields 1102 may at least be in part a result of charge separation between oxygen vacancies and aluminum vacancies, as well as other charged entities due to application of the voltage biasing described in association with FIG. 10A. In at least one implementation, residual electric fields 1102 decay with time. The decay of electric fields 1102 may represent relaxation of the charge separation over time. In at least one implementation, an objective of providing a slow voltage ramp up is to manage the charge relaxation time. In at least one implementation, residual electric fields 1102 are still present after placing a substrate on electrostatic chuck 200.

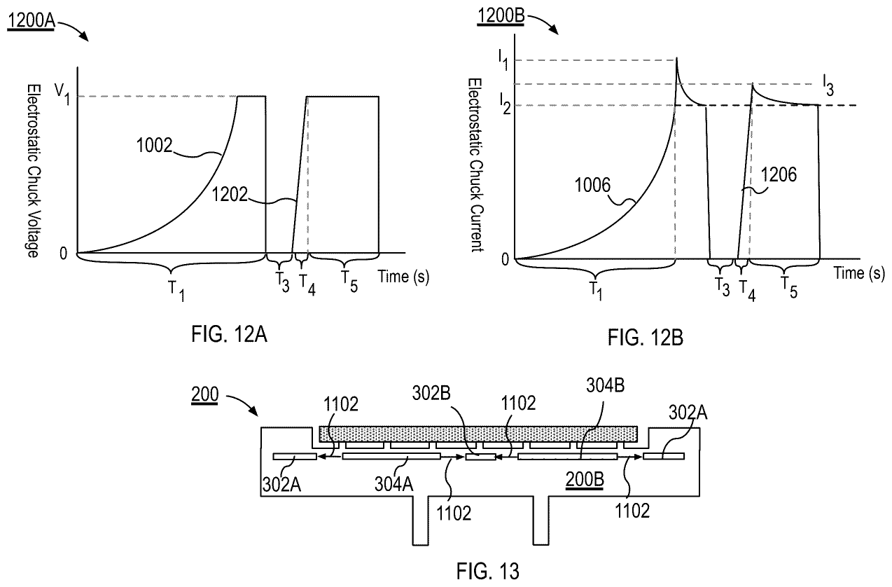

In at least one implementation, plots 1000A and 1000B illustrate a soft-conditioning procedure. In at least one implementation, a voltage signal can be initiated prior to insertion of a production substrate. This is described below in connection with FIGS. 12A-12B and FIG. 13.

FIG. 12A illustrates plot 1200A of conditioning voltage signal 1002 and program voltage signal 1202 in the time-domain. In at least one implementation, conditioning, or pre-charge voltage signal 1002 and program voltage signal 1202 are applied sequentially in time to one electrode (e.g., as a single-ended voltage) or both electrodes (e.g., as a differential voltage) in a pair of electrodes in an electrostatic chuck. In at least one implementation, (pre-charge) voltage signal 1002 and/or program voltage signal 1202 may be applied as a differential signal, where voltages of opposite polarity are applied to adjacent electrodes in a pair. In at least one implementation, voltage signal 1002 and voltage signal 1202 may be applied as single-ended signals, where one electrode in a pair is held at a reference (e.g., ground, or zero volt) potential. For example, voltage signal 1002 and voltage signal 1202 may be applied to one (e.g., as a single-ended volage) or both electrodes in opposite polarities (e.g., as a differential voltage) of an electrode pair such as electrodes 302A and 304A.

Plot 1200A includes many features of voltage signal 1002 described in association with plot 1000A in FIG. 10A. Referring again to FIG. 12A, in at least one implementation, plot 1200A includes program voltage signal 1202 which is applied after a duration T₃. In at least one implementation, duration T₃ is at least 5s but less than 180s. In at least one implementation, duration T₃ is sufficiently large enough to place a substrate on to an electrostatic chuck for processing (such as is shown in FIG. 13).

In at least one implementation, program voltage signal 1202 comprises a ramping phase, whereby a steady-state voltage level that is substantially equal to V₁ is reached over duration T₄. In at least one implementation, duration T₄ is at least 3s but may be less than 10s. In at least one implementation, program voltage signal 1202 further comprises holding voltage V₁ for duration T₅. In at least one implementation, duration T₅ is equal to or greater than a deposition or an etch time, which can be equal to at least 5s.

In at least one implementation, program voltage signal 1202 effectuates a current at a surface of electrostatic chuck that is illustrated in plot 1200B of current signals 1006 and 1206 resulting from application of voltage signals 1002 and 1202, shown in FIG. 12B. In at least one implementation, current signal 1206 comprises a ramp (e.g., a linear ramp following the voltage ramp of program voltage signal 1202, as shown) over a duration T₄, which may last between 3s and 30s. Current signal 1206 exhibits a transient current spike having a maximum I₃ that decays to a steady-stage current level I₂ over duration T₅. In at least one implementation, T₅ is at least 5s. In at least one implementation, I₃ is substantially less than I₁. For example, I₃ may be approximately one tenth of I₁. As noted above, the current spike and subsequent decay results from transient ionic current flow superimposed on the electronic current. In at least one implementation, current level 12, after duration T₅, is between 80 and 90% of current level I₃. In at least one implementation, I₂ in plot 1200B is indicative of residual electronic current flowing within the ceramic material of platen body 200B of electrostatic chuck 200, as depicted in FIG. 7B.

FIG. 13 is a cross-sectional illustration of an electrostatic chuck with substrate 114 placed on surface 200A of electrostatic chuck 200, at an end of duration T₂, in at least one implementation. In at least one implementation, application of program voltage signal 1202 indicates the beginning of process operation on substrate 114. In at least one implementation, residual electric fields 1102 stay laterally directed (as shown) in platen body 200B. In at least one implementation, relaxation of residual electric fields 1102 depends on charge mobility conditions. In at least one implementation, residual electric fields 1102 may relax partially, but not completely. In at least one implementation, when the field is applied again the final state or condition of program voltage V₁ is achieved more rapidly.

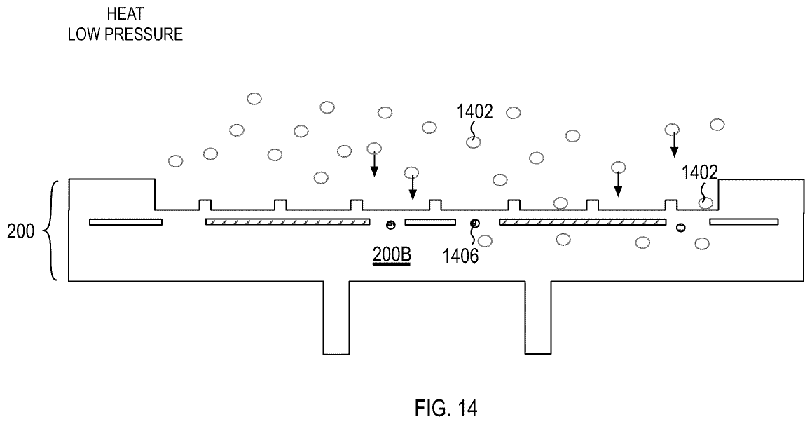

FIG. 14 is a cross-sectional illustration of electrostatic chuck 200 following a process to adsorb oxygen on surface 200C of electrostatic chuck 200, in at least one implementation. In at least one implementation, electrostatic chuck 200 includes platen body 200B which comprises a refractory dielectric (e.g., a ceramic) material, such as aluminum nitride (AlN), which may comprise oxygen impurities. In at least one implementation, the dielectric material comprises a population of oxygen vacancies. In at least one implementation, electrostatic chuck 200 is shown to be undergoing a high-temperature oxygen anneal process. In at least one implementation, gaseous oxygen (represented by a plurality of gaseous O₂ molecules 1402) may be introduced into a process chamber (e.g., process chamber 104 of plasma processing tool 100) at low pressure (e.g., 1 torr or less). The introduction of O₂ into the process chamber creates an oxygen atmosphere, enabling electrostatic chuck 200 to be exposed to the oxygen atmosphere within the process chamber. In at least one implementation, electrostatic chuck 200 may be heated to an elevated temperature by heater electrodes within electrostatic chuck 200. In at least one implementation, electrostatic chuck 200 may be heated to at least 500° Celsius during the oxygen anneal. For example, electrostatic chuck 200 may be heated to 650° Celsius.

In at least one implementation, during anneal process, O₂ molecules 1402 may adsorb onto surface 200C of electrostatic chuck 200. In at least one implementation, surface 200C may be a surface of dielectric material. In at least one implementation, upon adsorption O₂ molecules 1402 may diffuse into the bulk of the dielectric from surface 200C and dissociate at high temperature to interstitial oxygen atoms, or remain on surface 200C as dissociated oxygen atoms. In at least one implementation, surface oxygen atom radicals may diffuse into bulk of dielectric (interstitial oxygen atoms 1406). In at least one implementation, within bulk region of dielectric, interstitial oxygen atoms 1406 may diffuse along grain boundaries (e.g., grain boundaries 504 in FIG. 5).

Interstitial oxygen atoms 1406 may diffuse into grains (e.g., grains 502 in FIG. 5) and be reduced to oxygen ion species (e.g., O⁻, O₂⁻, O⁻²) by oxygen vacancies (e.g., anion vacancies 508 in FIG. 5). In at least one implementation, oxygen ions may ionically bond with an adjacent cation (e.g., an aluminum ion), and integrate into the lattice structure, healing oxygen vacancy within bulk of dielectric.

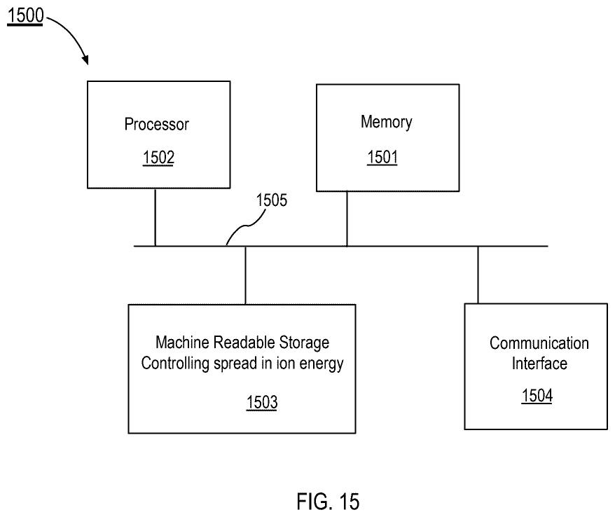

FIG. 15 illustrates processor system 1500 with machine-readable storage medium having instructions that when executed cause a processor to enhance ion energy and reduce ion energy distribution in an inductively coupled plasma, in accordance with various implementations. Processes described in at least one implementation may be stored in a machine-readable storage medium 1503 as computer-executable instructions. In at least one implementation, processor system 1500 comprises memory 1501, processor 1502, machine-readable storage medium 1503 (also referred to as tangible machine-readable medium), communication interface 1504 (e.g., wireless or wired interface), and network bus 1505 coupled together as shown.

In at least one implementation, processor 1502 is a Digital Signal Processor (DSP), an Application Specific Integrated Circuit (ASIC), a general-purpose Central Processing Unit (CPU), or a low power logic implementing a simple finite state machine to perform various processes described herein.

In at least one implementation, various logic blocks of processor system 1500 are coupled together via network bus 1505. Any suitable protocol may be used to implement network bus 1505. In at least one implementation, machine-readable storage medium 1503 includes instructions (also referred to as program software code/instructions) for enhancing ion energy and reducing ion angular spread in an inductively coupled plasma as described above with reference to various implementations.

In at least one implementation, machine-readable storage medium 1503 is a machine-readable storage medium with instructions for program voltage pulse to RF source coupled with electrostatic chuck 200. In at least one implementation, machine-readable storage medium 1503 has machine-readable instructions, that when executed, cause processor 1502 to perform a method of measuring and/or reporting as discussed with reference to various implementations.

In at least one implementation, program software code/instructions associated with various implementations may be implemented as part of an operating system or a specific application, component, program, object, module, routine, or other sequence of instructions or organization of sequences of instructions referred to as “program software code/instructions,” “operating system program software code/instructions,” “application program software code/instructions,” or simply “software” or firmware embedded in processor. In at least one implementation, program software code/instructions associated with processes of various implementations are executed by processor system 1500.

In at least one implementation, program software code/instructions associated with various implementations are stored in machine-readable storage medium 1503 and executed by processor 1502. In at least one implementation, machine-readable storage medium 1503 is a tangible machine-readable medium that can be used to store program software code/instructions and data that, when executed by a computing device, causes one or more processors (e.g., processor 1502) to perform a process. In at least one implementation, process may comprise controlling a pulsed voltage waveform. In at least one implementation, process may comprise controlling pulsed voltage waveform that is consistent with voltage signals described in association with FIGS. 10A and 12A.

Referring again to FIG. 15, in at least one implementation, machine-readable storage medium 1503 may include storage of executable software program code/instructions and data in various tangible locations, including for example ROM, volatile RAM, non-volatile memory and/or cache and/or other tangible memory as referenced herein. In at least one implementation, portions of this program software code/instructions and/or data may be stored in any one of these storage and memory devices. In at least one implementation, program software code/instructions can be obtained from other storage, including, e.g., through centralized servers or peer to peer networks and the like, including Internet. In at least one implementation, different portions of software program code/instructions and data can be obtained at different times and in different communication sessions or in the same communication session.

In at least one implementation, software program code/instructions associated with various implementations can be obtained in their entirety prior to execution of a respective software program or application. In at least one implementation, portions of software program code/instructions and data can be obtained dynamically, e.g., just in time, when needed for execution. In at least one implementation, some combination of these ways of obtaining software program code/instructions and data may occur, e.g., for different applications, components, programs, objects, modules, routines, or other sequences of instructions or organization of sequences of instructions. In at least one implementation, it may not be required that data and instructions be on a tangible machine-readable medium in entirety at a particular instance of time.

In at least one implementation, machine-readable storage medium 1503 include but are not limited to recordable and non-recordable type media such as volatile and non-volatile memory devices, read only memory (ROM), random access memory (RAM), flash memory devices, floppy and other removable disks, magnetic storage medium, optical storage medium (e.g., Compact Disk Read-Only Memory (CD ROMS), Digital Versatile Disks (DVDs), etc.), among others. In at least one implementation, software program code/instructions may be temporarily stored in digital tangible communication links while implementing electrical, optical, acoustical, or other forms of propagating signals, such as carrier waves, infrared signals, digital signals, etc. through such tangible communication links.

Besides what is described herein, various modifications may be made to at least one implementation thereof without departing from their scope. Therefore, illustrations of at least one implementation herein should be construed as examples, and not restrictive to scope of at least one implementation. Each example here in is indicative of at least one implementation, which can be combined with any other example.

Example 1 is an apparatus comprising: one or more circuitries to control generation of one or more ion vacancies in an electrostatic chuck based, at least in part, on a bias applied to the electrostatic chuck.

Example 2 is an apparatus according to any example herein, particularly example 1, wherein the bias applied to the electrostatic chuck comprises a conditioning voltage followed by a program voltage.

Example 3 is an apparatus according to any example herein, particularly example 2, wherein the conditioning voltage has a first ramp rate which is slower than a second ramp rate of the program voltage.

Example 4 is an apparatus according to any example herein, particularly example 2, wherein an end of the conditioning voltage and a beginning of the program voltage is separated in time.

Example 5 is an apparatus according to any example herein, particularly example 4, wherein the time is in a range of 5 seconds to 30 seconds.

Example 6 is an apparatus according to any example herein, particularly example 3, wherein the first ramp rate is between 50 V/s and 165 V/s.

Example 7 is an apparatus comprising: one or more circuitries to control generation of one or more ion vacancies in an electrostatic chuck based, at least in part, on an oxygen anneal process applied to the electrostatic chuck.

Example 8 is an apparatus according to any example herein, particularly example 7, wherein the oxygen anneal process is applied at a temperature of at least 500 degrees Celsius.

Example 9 is an apparatus according to any example herein, particularly example 7, wherein the oxygen anneal process is applied in an absence of a wafer on the electrostatic chuck.

Example 10 is an apparatus according to any example herein, particularly example 7, wherein the oxygen anneal process is carried out in chamber at a pressure of 1 Torr or less, wherein the electrostatic chuck is in the chamber.

Example 11 is a method of operating an electrostatic chuck, the method comprising: controlling generation of one or more ion vacancies in the electrostatic chuck based, at least in part, on applying a bias to the electrostatic chuck.

Example 12 is a method according to any example herein, particularly example 11, wherein applying the bias comprises: applying a conditioning voltage followed by a program voltage to the electrostatic chuck.

Example 13 is a method according to any example herein, particularly example 12, wherein the conditioning voltage has first a ramp rate which is slower than a second ramp rate of the program voltage.

Example 14 is a method according to any example herein, particularly example 13, wherein the first ramp rate is between 50 V/s to 165 V/s.

Example 15 is a method according to any example herein, particularly example 12, wherein an end of the conditioning voltage and a beginning of the program voltage is separated in time.

Example 16 is a method according to any example herein, particularly example 15, wherein the time is in a range of 5 seconds to 30 seconds.

Example 17 is a system comprising: a chamber comprising an electrostatic chuck coupled with a radio frequency (RF) voltage source; an RF generator coupled with coils above the chamber; and one or more circuitries to control generation of one or more ion vacancies in the electrostatic chuck based, at least in part, on a bias applied to the electrostatic chuck, wherein the bias is generated from the RF voltage source.

Example 18 is a system according to any example herein, particularly example 17, wherein the bias applied to the electrostatic chuck comprises a conditioning voltage followed by a program voltage.

Example 19 is a system according to any example herein, particularly example 18, wherein the conditioning voltage has a first ramp rate which is slower than a second ramp rate of the program voltage.

Example 20 is a system according to any example herein, particularly example 19, wherein the first ramp rate is between 50 V/s to 165 V/s.

Example 21 is a system according to any example herein, particularly example 18, wherein an end of the conditioning voltage and a beginning of the program voltage is separated in time.

Example 22 is a system according to any example herein, particularly example 21, wherein the time is in a range of 5 seconds to 30 seconds.

Example 23 is a method of operating an electrostatic chuck, the method comprising: generating a first voltage signal, the first voltage signal comprising: a ramp to a first voltage level over a first duration; and a first steady state voltage with the first voltage level for a second duration, wherein the first voltage signal effectuates a first current at a surface of the electrostatic chuck, wherein the first current comprises: a first current spike having a first magnitude; and a first current phase decaying to a second magnitude, wherein the second magnitude is less than the first magnitude; turning off the first voltage signal for a third duration; and generating a second voltage signal, the second voltage signal comprising: a ramp to a second voltage level over a fourth duration; and a second steady state voltage with the second voltage level for a fifth duration, wherein the second voltage signal effectuates a second current at the surface of the electrostatic chuck, wherein the second current comprises: a second current spike having a third magnitude; and a second current phase decaying to a fourth magnitude, wherein the fourth magnitude is less than the third magnitude.

Example 24 is a method according to any example herein, particularly example 23, wherein the first duration is at least 5s but less than 30s.

Example 25 is a method according to any example herein, particularly example 23, wherein the second duration is at least 5s but less than 30s.

Example 26 is a method according to any example herein, particularly example 23, wherein the first voltage level is between 700-1000 volts.

Example 27 is a method according to any example herein, particularly example 23, wherein the third duration is between 10s and 30s.

Example 28 is a method according to any example herein, particularly example 23, wherein the second magnitude is between 80% and 90% of the first magnitude.

Example 29 is a method according to any example herein, particularly example 23, wherein the first current spike reaches a peak at an end of the first duration.

Example 30 is a method according to any example herein, particularly example 23, wherein the first current spike is to decay to the first steady state current over the second duration.

Example 31 is a method according to any example herein, particularly example 23, wherein the fourth duration is at least 5s but less than 30s.

Example 32 is a method according to any example herein, particularly example 23, wherein the fifth duration is at least 5s.

Example 33 is a method according to any example herein, particularly example 23, wherein the second voltage level is between 700 volts and 1000 volts.

Example 34 is a method according to any example herein, particularly example 23, wherein the fourth magnitude is between 80% and 90% of the third magnitude.

Example 35 is a method according to any example herein, particularly example 23, wherein the second current spike is to decay to the second steady state voltage over the fifth duration.

Example 36 is a method according to any example herein, particularly example 23, wherein turning off the first voltage signal leaves at a residual transverse electric field between two oppositely charged electrodes in a vicinity of a surface of the electrostatic chuck.

Example 37 is a method according to any example herein, particularly example 23, wherein after turning off the first voltage signal, a substrate is placed on the electrostatic chuck prior to turning on the second voltage signal.

Example 38 is a method according to any example herein, particularly example 37, wherein the substrate is placed on the electrostatic chuck prior to turning on the second voltage signal but after the third duration.

Example 39 is an electrostatic chuck comprising a first electrode disposed substantially at the periphery of a dielectric platen body; and a second electrode disposed substantially along a diameter of the dielectric platen body.

Example 40 is an electrostatic chuck according to any example herein, particularly example 39, further comprising a third electrode and a fourth electrode, wherein the third electrode and fourth electrode are symmetrically disposed substantially between the first electrode and the second electrode.

Example 41 is an electrostatic chuck according to any example herein, particularly example 40, wherein the third electrode and the fourth electrode have a semicircular shape, and wherein the third electrode and the fourth electrode extend between a central portion of the dielectric platen body to a peripheral portion of the dielectric platen body.

Example 42 is a method for operating a plasma deposition apparatus, the method comprising: applying a first voltage ramp over a first duration from a reference voltage level to a first steady-state voltage level, wherein the first voltage ramp is applied between at least two electrodes within a dielectric portion of an electrostatic chuck; holding the first steady-state voltage level for a second duration; stepping the first steady-state voltage level to the reference voltage level; holding the reference voltage level for a third duration; applying a second voltage ramp over a fourth duration from the reference voltage level to a second steady-state voltage level between the at least two electrodes within the dielectric portion of the electrostatic chuck; and holding the second steady-state voltage level for a fifth duration.

Example 43 is a method according to any example herein, particularly example 42, wherein the first duration and the second duration are dependent on a charge mobility of one or more mobile charged species within the dielectric portion of the electrostatic chuck.

Example 44 is a method according to any example herein, particularly example 43, wherein the mobile charged species comprise one or more oxygen ion vacancies, cation vacancies and interstitial ions within the dielectric portion of the electrostatic chuck.

Example 45 is a method according to any example herein, particularly example 42, wherein the first voltage ramp is applied at a first rate, wherein the second voltage ramp is applied at a second rate that is greater than the first rate.

Example 46 is a method according to any example herein, particularly example 45, wherein the first rate is between 50 V/s and 165 V/s.

Example 47 is a method according to any example herein, particularly example 42, wherein the first steady-state voltage level and the second steady-state voltage level are between 300 volts and 6000 volts.

Example 48 is a method according to any example herein, particularly example 42, wherein the second steady-state voltage level is between 80% and 90% of the first steady-state voltage level.

Example 49 is a method according to any example herein, particularly example 42, further comprising conducting an oxygen anneal process, wherein the electrostatic chuck is exposed to an oxygen atmosphere within the plasma deposition apparatus.

Example 50 is a method according to any example herein, particularly example 49, wherein the oxygen atmosphere is held at a pressure of 1 torr or less.

Example E 51 is a method according to any example herein, particularly example 49, wherein the oxygen anneal process is applied at a temperature of at least 500 degrees Celsius.

Example 52 is a method according to any example herein, particularly example 42, wherein the first duration is at least 5s but less than 180s; wherein the second duration is at least 5s but less than 180s; wherein the third duration is between 10s and 30s; wherein the fourth duration is at least 5s but less than 180s; and wherein the fifth duration is at least 5s.

What is claimed is:

1. A method for operating a plasma deposition apparatus, the method comprising:
applying a first voltage ramp over a first duration from a reference voltage level to a first steady-state voltage level, wherein the first voltage ramp is applied between at least two electrodes within a dielectric portion of an electrostatic chuck;
holding the first steady-state voltage level for a second duration;
stepping the first steady-state voltage level to the reference voltage level;
holding the reference voltage level for a third duration;
applying a second voltage ramp over a fourth duration from the reference voltage level to a second steady-state voltage level between the at least two electrodes within the dielectric portion of the electrostatic chuck; and
holding the second steady-state voltage level for a fifth duration.

2. The method of claim 1, wherein the first duration and the second duration are dependent on a charge mobility of one or more mobile charged species within the dielectric portion of the electrostatic chuck.

3. The method of claim 2, wherein the mobile charged species comprise one or more oxygen ion vacancies, cation vacancies, and interstitial ions within the dielectric portion of the electrostatic chuck.

4. The method of claim 1, wherein the first voltage ramp is applied at a first rate, wherein the second voltage ramp is applied at a second rate that is greater than the first rate.

5. The method of claim 4, wherein the first rate is between 50 V/s and 165 V/s.

6. The method of claim 1, wherein the first steady-state voltage level and the second steady-state voltage level are between 300 volts and 6000 volts.

7. The method of claim 1, wherein the second steady-state voltage level is between 80% and 90% of the first steady-state voltage level.

8. The method of claim 1, wherein stepping the first steady-state voltage level to the reference voltage level leaves one or more residual transverse electric fields between two oppositely charged electrodes in a vicinity of a surface of the electrostatic chuck.

9. The method of claim 1, wherein after stepping the first steady-state voltage level to the reference voltage level, a substrate is placed on the electrostatic chuck prior to applying the second voltage ramp.

10. The method of claim 9, wherein the substrate is placed on the electrostatic chuck prior to applying the second voltage ramp but after the third duration.

11. The method of claim 1, further comprising conducting an oxygen anneal process, wherein the electrostatic chuck is exposed to an oxygen atmosphere within the plasma deposition apparatus.

12. The method of claim 11, wherein the oxygen atmosphere is held at a pressure of 1 torr or less.

13. The method of claim 11, wherein the oxygen anneal process is applied at a temperature of at least 500 degrees Celsius.

14. The method of claim 1, wherein:
the first duration is at least 5s but less than 180s;
the second duration is at least 5s but less than 180s;
the third duration is between 10s and 30s; and
the fourth duration is at least 5s but less than 180s; and
wherein the fifth duration is at least 5s.

15. An electrostatic chuck, comprising:
a first electrode disposed substantially at a periphery of a dielectric platen body; and
a second electrode disposed substantially along a diameter of the dielectric platen body.

16. The electrostatic chuck of claim 15, further comprising a third electrode and a fourth electrode, wherein the third electrode and the fourth electrode are symmetrically disposed substantially between the first electrode and the second electrode.

17. The electrostatic chuck of claim 16, wherein the third electrode and the fourth electrode have a semicircular shape, and wherein the third electrode and the fourth electrode extend between a central portion of the dielectric platen body to a peripheral portion of the dielectric platen body.

18. A system comprising:
a chamber comprising an electrostatic chuck coupled with a radio frequency (RF) voltage source;
an RF generator coupled with coils above the chamber; and
one or more circuitries to control generation of one or more ion vacancies in the electrostatic chuck based, at least in part, on a bias applied to the electrostatic chuck, wherein the bias is generated from the RF voltage source.

19. The system of claim 18, wherein the bias applied to the electrostatic chuck comprises a pre-charge voltage followed by a program voltage.

20. The system of claim 19, wherein the pre-charge voltage has a first ramp rate which is slower than a second ramp rate of the program voltage.

21. The system of claim 19, wherein an end of the pre-charge voltage and a beginning of the program voltage is separated in time.

22. An apparatus comprising:
one or more circuitries to control generation of one or more ion vacancies in an electrostatic chuck based, at least in part, on an oxygen anneal process applied to the electrostatic chuck.

23. The apparatus of claim 22, wherein the oxygen anneal process is applied at a temperature of at least 500 degrees Celsius.

24. The apparatus of claim 23, wherein the oxygen anneal process is applied in an absence of a wafer on the electrostatic chuck.

25. The apparatus of claim 23, wherein the oxygen anneal process is carried out in chamber at a pressure of 1 Torr or less, wherein the electrostatic chuck is in the chamber.
